(19) United States
(12) Patent Application Publication
(10) Pub. No.: US 2014/0076602 A1
(43) Pub. Date: Mar. 20, 2014

(54) HERMETIC SEALING OF ATOMIC SENSOR USING SOL-GEL TECHNIQUE

(71) Applicant: HONEYWELL INTERNATIONAL INC., Morristown, NJ (US)

(72) Inventors: Christina Marie Schober, St. Anthony, MN (US); Tim Goldberg, St. Paul, MN (US); James A. Vescera, Hopkins, MN (US); Delmer L. Smith, Edina, MN (US); Terry Dean Stark, St. Louis Park, MN (US)

(73) Assignee: HONEYWELL INTERNATIONAL INC., Morristown, NJ (US)

(21) Appl. No.: 13/622,074

(22) Filed: Sep. 18, 2012

(51) Int. Cl. B05D 7/24; H05K 5/06; C03C 27/10

(52) U.S. Cl. 174/50.5; 156/325; 427/140

(57) ABSTRACT

A method of forming a physics package for an atomic sensor comprises providing a plurality of panels, with each of the panels having multiple edges, and assembling the panels in a three-dimensional multi-faced geometric configuration such that the edges of adjacent panels are aligned with each other. A sol-gel material is applied to the edges of the panels, and the sol-gel material is cured to hermetically seal adjacent panels together.

### STATEMENT REGARDING FEDERALLY SPONSORED RESEARCH OR DEVELOPMENT

This invention was made with Government support under contract No. W31P4Q-09-C-0348 awarded by the U.S. Army. The Government has certain rights in the invention.

### BACKGROUND

Primary time standards such as atomic clocks have traditionally been relatively large table top devices. For example, a physics package of a conventional atomic clock tends to be large and requires an expensive support system. Reducing the size of primary time standards such as by reducing the size of the physics package is desirable in many applications. However, making the physics package smaller has unique and complex challenges, since the physics package requires multiple windows, mirrors, and a hermetic seal of non-magnetic materials.

Smaller size requirements for atomic clocks is challenging current building techniques. In addition, the size reduction of atomic clocks affects their performance as the minors and windows shrink. Furthermore, the internal volume reduction adversely affects performance of the atomic clocks.

Current methods for manufacturing the physics package for an atomic clock include machining a glass body with multiple holes for attaching high temperature frit mirrors, windows and fill ports with a fixturing apparatus. Sometimes a leak or seal opening occurs during manufacture with frit, which typically requires adding a mixture of frit paste to the leak area, re-fixturing the entire physics package, and sending the physics package back through a frit furnace. This requires complete disassembly from a fill station if the leak is not found right away while still in the fixturing apparatus.

In some instances, silicone gels have been used on vacuum station mounted clocks to temporarily seal leaks. However, silicone is a highly migratable and not easily cleaned. Thus, the silicone can contaminate laboratories and factories, as well as prevent bonding so that contaminated products have to be scrapped.

### SUMMARY

A method of forming a physics package for an atomic sensor comprises providing a plurality of panels, with each of the panels having multiple edges, and assembling the panels in a three-dimensional multi-faced geometric configuration such that the edges of adjacent panels are aligned with each other. A sol-gel material is applied to the edges of the panels, and the sol-gel material is cured to hermetically seal adjacent panels together.

### BRIEF DESCRIPTION OF THE DRAWINGS

Understanding that the drawings depict only exemplary embodiments and are not therefore to be considered limiting in scope, the exemplary embodiments will be described with additional specificity and detail through the use of the accompanying drawings, in which:

FIG. 1 illustrates a physics block for a physics package of an atomic sensor according to one embodiment that is hermetically sealed with a sol-gel material.

### DETAILED DESCRIPTION

In the following detailed description, embodiments are described in sufficient detail to enable those skilled in the art to practice the invention. It is to be understood that other embodiments may be utilized without departing from the scope of the invention. The following detailed description is, therefore, not to be taken in a limiting sense.

A method for hermetically sealing an atomic sensor utilizes a solution gel (sol-gel) technique. The present method can be applied to building a new physics package for an atomic sensor, and to the repair or rework of an existing physics package. In addition, a physics package that is hermetically sealed with a sol-gel material is provided.

The present approach can eliminate the need for high temperature frit processing by using a sol-gel material (also known as liquid glass) to hermetically seal the physics package of an atomic sensor such as an atomic clock. A hermetic seal can be achieved by the sol-gel wicking and sealing the mating edges of the components of the physics package. Alternatively, the sol-gel material can be applied as a fillet or skin on the exterior of the components to seal the components of the physics package together.

The sol-gel material is applied as a permanent seal, and can be applied at room temperature, cured at room temperature or with minimal heat, and when fully cured is capable of high temperature processing. For example, when a sol-gel seal is cured it will survive vacuum station processing and heating up to about 300° C. The sol-gel material is advantageous in that no contaminates are generated during sealing of the physics package.

In an exemplary method of forming a physics package for an atomic sensor, a plurality of panels is provided that includes various windows and minors. The panels can be formed of glass or other optical materials. The panels are assembled in a three-dimensional multi-faced geometric configuration such that edges of adjacent panels are aligned with each other at a plurality of seams. For example, various optical panels can be assembled around a support framework and fixtured in place so that edges of the panels are aligned together. A sol-gel material is then applied to all of the seams of adjoining panels. Alternatively, the sol-gel material can be applied to the edges of the panels prior to assembly of the panels around the support framework. Capillary action, wicking, or diffusion of the sol-gel material can be used to fill in the seams of the panels after application. A dye may be optionally added to the sol-gel material to aide in ensuring all seams are covered with the sol-gel material. The sol-gel material may have bubbles prior to or after application, so a vacuum processing step can be added to remove bubbles from the stock and/or applied sol-gel material.

The sol-gel material is then cured to hermetically seal the panel seams. As shrinkage occurs during curing, adequate sol-gel material is needed to maintain the seal of the panel seams. The assembled panels can be processed to phase separate the liquid (solvent) in the sol-gel material. For example, a centrifuge process can be used to speed up the phase separation. Afterwards, a low temperature thermal treatment can be performed to enhance mechanical properties for structural stability of the seal. This thermal treatment is a low temperature firing for sintering, densification, and grain growth.

The sol-gel material utilized in the present technique can include various chemicals. Suitable examples include sodium silicate, potassium silicate, zirconia, silicon dioxide, sodium methoxide, or other metal alkoxides. The sol-gel material can be applied in a solution or gel form. The sol-gel material can be applied manually, such as with a syringe, or by use of a conventional coating process such as spin coating or dip coating. When using a coating process, areas that are not to be coated with the sol-gel material can be covered with a mask.

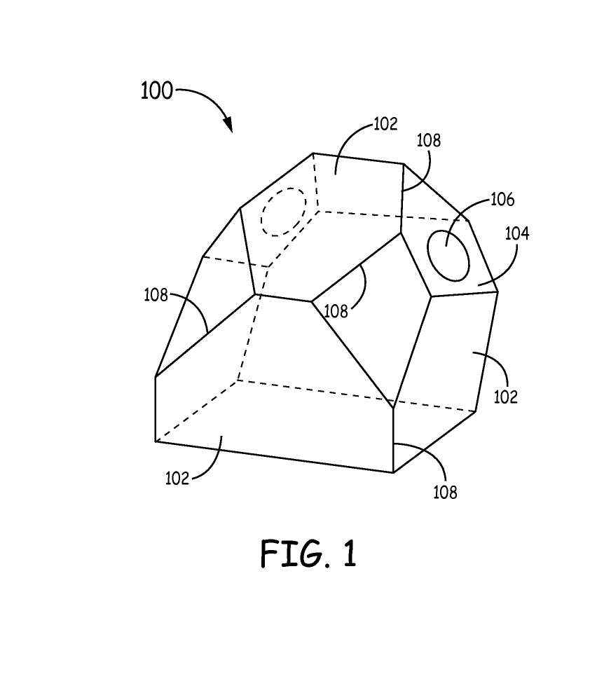

FIG. 1 illustrates a physics block 100 for a physics package of an atomic sensor according to one embodiment that is sealed according to the present technique. The physics block 100 includes a plurality of panels 102, including windows and minors, which have various polygonal shapes that are assembled into a three-dimensional structure having a multi-faced geometry. At least one panel 104 has a fill tube aperture 106. The edges of panels 102, 104 are aligned at a plurality of seams 108 and hermetically sealed together with a sol-gel material. The sealed physics block 100 is configured to enclose an internal vacuum chamber for the physics package.

The present technique can also be utilized in repairing or reworking a physics package for an atomic sensor. When a leak or fissure in the physics package is detected, a sol-gel material is applied to the area of the leak or fissure. The sol-gel material is then cured to seal the leak or fissure. The repair or rework can be done while the physics package is mounted to a vacuum station without having to disassemble the parts of the physics package.

The present method can be used to repair leaks or fissures of hermetic seals previously made with frit, or to seal glass fissures, cracks, or other material seal defects. For example, a leaky frit seal in an atomic clock can be easily repaired rather than being sent back for a long rework cycle through frit processing. In addition, the sol-gel material can be used to patch a leaky assembly that was previously sealed with an optical seal, a metal seal, or a sol-gel material. The sol-gel patch can be applied by wicking, as well as skin or blob formation. The patching of leaky seals or cracks in an atomic sensor body allows a built atomic sensor to be to salvaged rather than scrapped.

In addition, the present technique can also be used to seal fissures on internal surfaces of an atomic sensor to prevent “virtual” leaks in a physics package. A virtual leak is a source of gas trapped within a chamber and caused by a very small fissure such as an internal weld crack. While the gas does not leak to the outside, it can change the pressure in the internal chamber of the physics package. The sol-gel material can be applied to such a crack to repair the virtual leak and keep the crack from propagating.

In an exemplary method for manually applying a sol-gel material, the parts to be assembled or area/crack to be patched are cleaned, such as by degreasing, applying ozone, organic clean, oxide strip, ionic clean, deionized water rinse, O₂ plasma, or the like. The sol-gel material is then applied with a syringe to cover the seal area. After the solution is applied, light pressure or gravity is used so that the components are not subject to disengagement. For example, a panel such as a mirror can be held with light pressure if not fixtured.

The sol-gel material forms a skin quickly and dries from the outside in, so holding it in place ensures a full cure at room temperature. A higher cure temperature may be needed or used to set up the sol-gel material more quickly, and then an even higher curing temperature can be used.

The sol-gel material can be shaped into various gel preforms for convenience during atomic sensor builds or reworks. For example, the sol-gel material can be cast into a suitable container with a desired shape of the preform. The sol-gel preforms can be applied to the panels and held in place by their stickiness, by gravity, or by using a liquid sol-gel as a tacking fluid.

### EXAMPLE EMBODIMENTS

Example 1 includes a method of forming a physics package for an atomic sensor, the method comprising: providing a plurality of panels, each of the panels having multiple edges; assembling the panels in a three-dimensional multi-faced geometric configuration such that the edges of adjacent panels are aligned with each other; applying a sol-gel material to the edges of the panels; and curing the sol-gel material to hermetically seal adjacent panels together.

Example 2 includes the method of Example 1, wherein the panels comprise glass panels.

Example 3 includes the method of Example 2, wherein the glass panels comprise windows or minors.

Example 4 includes the method of any of Examples 1-3, wherein the sol-gel material comprises sodium silicate, potassium silicate, zirconia, silicon dioxide, sodium methoxide, or a metal alkoxide.

Example 5 includes the method of any of Examples 1-4, wherein the sol-gel material is applied with a syringe.

Example 6 includes the method of any of Examples 1-4, wherein the sol-gel material is applied by spin coating or dip coating.

Example 7 includes the method of any of Examples 1-6, wherein the sol-gel material is cured at room temperature.

Example 8 includes the method of any of Examples 1-7, wherein the physics package is configured for an atomic clock.

Example 9 includes a physics package for an atomic sensor, the physics package comprising: a plurality of panels coupled together in a three-dimensional multi-faced geometric configuration such that edges of adjacent panels are aligned with each other at a plurality of seams; and a cured sol-gel material that hermetically seals the seams.

Example 10 includes the physics package of Example 9, wherein the panels comprise glass panels.

Example 11 includes the physics package of Example 10, wherein the glass panels comprise windows or minors.

Example 12 includes the physics package of any of Examples 9-11, wherein the sol-gel material comprises sodium silicate, potassium silicate, zirconia, silicon dioxide, sodium methoxide, or a metal alkoxide.

Example 13 includes the physics package of any of Examples 9-12, wherein the physics package is configured for an atomic clock.

Example 14 includes a method of repairing a physics package for an atomic sensor, the method comprising: detecting a leak or fissure in the physics package; applying a sol-gel material to the leak or fissure; and curing the sol-gel material to seal the leak or fissure.

Example 15 includes the method of Example 14, wherein the sol-gel material comprises sodium silicate, potassium silicate, zirconia, silicon dioxide, sodium methoxide, or a metal alkoxide.

Example 16 includes the method of any of Examples 14-15, wherein the leak or fissure is in one or more glass panels of the physics package.

Example 17 includes the method of Example 16, wherein the glass panels comprise windows or minors.

Example 18 includes the method of any of Examples 14-17, wherein the sol-gel material is applied with a syringe.

Example 19 includes the method of any of Examples 14-18, wherein the sol-gel material is cured at room temperature.

Example 20 includes the method of any of Examples 14-19, wherein the physics package is configured for an atomic clock.

The present invention may be embodied in other forms without departing from its essential characteristics. The described embodiments are to be considered in all respects only as illustrative and not restrictive. Therefore, it is intended that this invention be limited only by the claims and the equivalents thereof.

What is claimed is:

1. A method of forming a physics package for an atomic sensor, the method comprising:
providing a plurality of panels, each of the panels having multiple edges;
assembling the panels in a three-dimensional multi-faced geometric configuration such that the edges of adjacent panels are aligned with each other;
applying a sol-gel material to the edges of the panels; and
curing the sol-gel material to hermetically seal adjacent panels together.

2. The method of claim 1, wherein the panels comprise glass panels.

3. The method of claim 2, wherein the glass panels comprise windows or minors.

4. The method of claim 1, wherein the sol-gel material comprises sodium silicate, potassium silicate, zirconia, silicon dioxide, sodium methoxide, or a metal alkoxide.

5. The method of claim 1, wherein the sol-gel material is applied with a syringe.

6. The method of claim 1, wherein the sol-gel material is applied by spin coating or dip coating.

7. The method of claim 1, wherein the sol-gel material is cured at room temperature.

8. The method of claim 1, wherein the physics package is configured for an atomic clock.

9. A physics package for an atomic sensor, the physics package comprising:
a plurality of panels coupled together in a three-dimensional multi-faced geometric configuration such that edges of adjacent panels are aligned with each other at a plurality of seams; and
a cured sol-gel material that hermetically seals the seams.

10. The physics package of claim 9, wherein the panels comprise glass panels.

11. The physics package of claim 10, wherein the glass panels comprise windows or mirrors.

12. The physics package of claim 9, wherein the sol-gel material comprises sodium silicate, potassium silicate, zirconia, silicon dioxide, sodium methoxide, or a metal alkoxide.

13. The physics package of claim 9, wherein the physics package is configured for an atomic clock.

14. A method of repairing a physics package for an atomic sensor, the method comprising:
detecting a leak or fissure in the physics package;
applying a sol-gel material to the leak or fissure; and
curing the sol-gel material to seal the leak or fissure.

15. The method of claim 14, wherein the sol-gel material comprises sodium silicate, potassium silicate, zirconia, silicon dioxide, sodium methoxide, or a metal alkoxide.

16. The method of claim 14, wherein the leak or fissure is in one or more glass panels of the physics package.

17. The method of claim 16, wherein the glass panels comprise windows or mirrors.

18. The method of claim 14, wherein the sol-gel material is applied with a syringe.

19. The method of claim 14, wherein the sol-gel material is cured at room temperature.

20. The method of claim 14, wherein the physics package is configured for an atomic clock.
